(19) United States
(12) Patent Application Publication
(10) Pub. No.: US 2020/0152534 A1
(43) Pub. Date: May 14, 2020

(54) SEMICONDUCTOR COMPONENT AND METHOD FOR PRODUCING A SEMICONDUCTOR COMPONENT

(71) Applicant: OSRAM Opto Semiconductors GmbH, Regensburg (DE)

(72) Inventors: Christian LEIRER, Friedberg (DE); Christian MUELLER, Deuerling (DE); Isabel OTTO, Regenstauf (DE)

(21) Appl. No.: 16/615,869

(22) PCT Filed: May 17, 2018
(86) PCT No.: PCT/EP2018/062973

§ 371 Date: Nov. 22, 2019

(30) Foreign Application Priority Data
May 23, 2017 (DE) 10 2017 111 277.4

(51) Int. Cl. H01L 23/31; H01L 21/56

(52) U.S. Cl. CPC H01L 23/315; H01L 21/565

(57) ABSTRACT

A semiconductor component may have a semiconductor body, an electrically conductive carrier layer, and an electrically poorly conductive insulation. The semiconductor body may include a first semiconductor layer and a second semiconductor layer, a first main face and a second main face, situated opposite the first main face, wherein the first main face is formed by a surface of the first semiconductor layer and the second main face is formed by a surface of the second semiconductor layer. The electrically conductive carrier layer may regionally cover the second main face the carrier layer is structured in such a way that it has at least one contact-free depression. The insulation may be located between the carrier layer and the semiconductor body and covers at least part of the second main face and extends up to at least one lateral face of the semiconductor body.

### CROSS-REFERENCE TO RELATED APPLICATIONS

The present application is a national stage entry according to 35 U.S.C. § 371 of PCT application No.: PCT/EP2018/062973 filed on May 17, 2018; which claims priority to German Patent Application Serial No.: 10 2017 111 277.4, which was filed on May 23, 2017; both of which are incorporated herein by reference in their entirety and for all purposes.

### TECHNICAL FIELD

A semiconductor component and a method for producing a semiconductor component are provided.

### BACKGROUND

In semiconductor components, defects, for example cracks or delaminations, may occur under mechanical loads because of comparatively poor deformability of some layers of material and can spread and impair the quality of the semiconductor components.

### SUMMARY

One object to be achieved in the present case is that of providing a mechanically stable semiconductor component. Another object to be achieved is that of providing a method for producing such a semiconductor component.

According to at least one embodiment, the semiconductor component includes a semiconductor body, which has a first semiconductor layer and a second semiconductor layer. Furthermore, the semiconductor body has a first main face and a second main face, opposite from the first main face, in particular the first main face being formed by a surface of the first semiconductor layer and the second main face being formed by a surface of the second semiconductor layer. In particular, the first main face and the second main face delimit the semiconductor body in a vertical direction.

Furthermore, the semiconductor body has at least one side face, which joins the first main face to the second main face. The number of side faces is determined by the geometry of the semiconductor body. In particular, the semiconductor body has multiple side faces. This is the case for example when the semiconductor chip is of a cuboidal form and correspondingly has four side faces. The at least one side face is arranged largely transversely to the first and second main faces. “Transversely” means that a normal vector of the side face does not run parallel to a normal vector of the first and/or second main faces. In a non-limiting embodiment, the at least one side face delimits the semiconductor body in one or more lateral directions. The lateral directions are arranged in a plane of which the normal vector is arranged parallel to the vertical direction. In particular, the direction in which the second semiconductor layer follows the first semiconductor layer is referred to as the vertical direction.

Furthermore, the at least one side face may be a face that is made up of at least two sub-faces. For example, the sub-faces may be planar faces, in particular the surface normals of two sub-faces that are adjacent to one another running transversely, that is to say not parallel, to one another.

The first semiconductor layer may have a first conductivity and the second semiconductor layer may have a second conductivity. In a non-limiting embodiment, the first semiconductor layer is an n-conducting layer. Furthermore, the second semiconductor layer is in particular a p-conducting layer. The semiconductor body may have further semiconductor layers between the first and second semiconductor layers.

According to at least one embodiment, in the present case the semiconductor component is an optoelectronic component. Here, the semiconductor body has an active zone, which is suitable for radiation generation or for radiation detection. In particular, the active zone is a p-n junction zone. The active zone may in this case be formed as one layer or as a series of multiple layers. For example, during the operation of the semiconductor component the active zone emits electromagnetic radiation, for instance in the visible, ultraviolet or infrared spectral range. Alternatively, during the operation of the semiconductor component the active zone may absorb electromagnetic radiation and convert it into electrical signals or electrical energy. The active zone is in particular arranged between the first semiconductor layer and the second semiconductor layer.

Materials based on nitride-compound semiconductors come into consideration for the layers of the semiconductor body. “Based on nitride-compound semiconductors” means in the present context that at least one layer of the semiconductor body includes a nitride-III/V compound semiconductor material, AlₙGaₘIn₁₋ₙ₋ₘN, where 0≤n 1, 0≤m 1 and n≤m 1. This material does not in this case necessarily have to have a mathematically exact composition in accordance with the above formula. Rather, it may include one or more dopants as well as additional constituents that do not substantially change the characteristic physical properties of the AlₙGaₘIn₁₋ₙ₋ₘN material. For the sake of simplicity, however, the above formula only includes the essential constituents of the crystal lattice (Al, Ga, In, N), even if they can to some extent be substituted by small amounts of further substances.

Furthermore, the semiconductor component may have an electrically conducting carrier layer. The carrier layer has in this case a comparatively low electrical resistance. In addition, because of its nature, for example its thickness and/or its material, the carrier layer is a stabilizing component of the semiconductor component. The thickness of the carrier layer may be between 2 μm and 100 μm inclusive, in particular between 5 μm and 30 μm, between 5 μm and 15 μm, deviations from the values specified of up to 10% being tolerable. The thickness is a maximum extent of the carrier layer in a direction that is arranged perpendicularly to a main plane of extent of the carrier layer.

According to at least one embodiment, the carrier layer is a metallic layer. A “metallic layer” should be understood in this case as meaning a layer that is formed by a metal or metal compound and is distinguished by at least one of the following properties: high electrical conductivity, which decreases with increasing temperature, high thermal conductivity, ductility (deformability), metallic gloss (mirror finish). For example, Au, Zn, Al, Sn, Ni and Cu or compounds of these materials, such as for example AuSn and NiAu and additionally NiPdAu, come into consideration for the carrier layer. The carrier layer may therefore contain at least one of these materials or consist of one of these materials. The carrier layer is in particular a galvanic layer, which is galvanically deposited on a starting layer (seed layer) arranged on the semiconductor body. For example, the starting layer may contain one of the materials Au, Cu, Ti, Al, Ag, Sn, Rh, Ni or Pt or consist of one of these materials.

In a non-limiting embodiment, the second main face is covered at least in certain regions by the carrier layer. It is in this case possible that the carrier layer is for the greater part formed without any interruption, so that the second main face is covered to at least 50%, in particular to at least 80%, with preference to at least 90%, by the carrier layer. The carrier layer therefore has in particular only a few locations at which there are interruptions, that is to say regions of reduced thickness.

According to at least one embodiment, the semiconductor component has an electrically weakly conducting insulation, which is arranged between the carrier layer and the semiconductor body. In particular, the insulation is electrically non-conducting during operation. Electrically weakly conducting or insulating materials, such as for example a stoichiometric or non-stoichiometric composition of silicon oxide, silicon nitride, aluminum oxide or titanium oxide, come into consideration for the insulation. The insulation contributes in particular to an electrical insulation of various electrical terminals and/or of semiconductor layers of various electrical conductivities of the semiconductor component.

In the case of a non-limiting refinement, the second main face is covered at least in certain regions by the insulation. Interruptions of the insulation may occur in particular in regions that are intended for the electrical contacting of the semiconductor body. Furthermore, the insulation may extend from the second main face to at least one side face of the semiconductor body. In particular, the insulation extends from the second main face to at least one side face of the first semiconductor layer. In this case, at least one side face of the second semiconductor layer may be completely covered by the insulation. In particular, all of the side faces of the semiconductor body are completely covered by the insulation.

According to at least one embodiment, the insulation has a first insulating layer and a second insulating layer. The second insulating layer is arranged in particular on a side of the first insulating layer that is facing away from the semiconductor body. In a non-limiting embodiment, the first and second insulating layers differ from one another in their stiffness and/or elasticity. In the present case, the “elasticity” refers in particular to the elastic properties of the material used for the various layers. Furthermore, the “stiffness” refers in particular to the resistance of a body to elastic deformation due to a force or a moment, for example a bending moment or a torsional moment. The stiffness of a layer depends not only on the elastic properties of the material used, but also decisively on the geometry of the layer.

For example, the two insulating layers may be formed from the same material and have an equally great elasticity. In particular, the stiffness of the one insulating layer is in this case higher than the stiffness of the other insulating layer. This may be achieved for example by the two insulating layers differing in their geometrical shape.

Alternatively, the two insulating layers may be formed from different materials and have different elasticities.

Advantageously, one of the two insulating layers is more easily deformable or more compliant than the other insulating layer, so that stresses that occur for example during the assembly or production of the semiconductor component can be reduced better by means of one of the two insulating layers than by the other. It is also possible that stresses are specifically reduced by the more rigid insulating layer, which is formed with a lower elasticity and/or a greater stiffness, in that it serves as a predetermined breaking point. Overall, mechanical loads in the semiconductor component can therefore be specifically reduced by the first or second insulating layer.

According to at least one embodiment, the second insulating layer has a structuring in such a way that at least one cavity in which the second insulating layer is stripped away is formed between the insulation and the carrier layer. The first insulating layer is in this case of an unstructured form. In particular, the structuring of the second insulating layer, that is to say an altered geometrical shape of the second insulating layer, can have the effect that the stiffness of the second insulating layer is reduced as compared to the first insulating layer, even when there is equally great elasticity of the insulating layers.

According to at least one embodiment, the first insulating layer has a structuring in such a way that at least one cavity in which the first insulating layer is stripped away is formed between the semiconductor body and the carrier layer. The second insulating layer is in this case of an unstructured form. In particular, the structuring of the first insulating layer, that is to say an altered geometrical shape of the first insulating layer, can have the effect that the stiffness of the first insulating layer is reduced as compared to the second insulating layer, even when there is equally great elasticity.

In the case of a non-limiting refinement, the cavity may extend from the first main face of the semiconductor component, along at least one side face of the semiconductor body, in the direction of the second main face of the semiconductor body. The cavity may surround the semiconductor body laterally around the full periphery. Alternatively, a number of cavities may be provided in the first or second insulating layer, a region of the first insulating layer or second insulating layer being respectively arranged between two cavities. The cavity allows the various layers in the semiconductor component to have space for slight flexural distortions, without directly causing defects in the semiconductor component.

Thicknesses in a range from 50 nm to 2 μm, between 100 nm and 500 nm, come into consideration for the first and second insulating layers, the limits being included. Deviations from the values specified of up to 10% are tolerable here.

In the case of a non-limiting refinement, the insulation is conformally covered by the carrier layer. This means in particular that delimiting areas of the insulation and the carrier layer that are facing one another are identical with respect to their geometrical shape.

According to at least one embodiment, at least one side face of the semiconductor component is formed in certain regions by a side face of the insulation. In this case, the side face of the semiconductor component may be formed in certain regions either only by a side face of the first insulating layer or only by a side face of the second insulating layer. However, it is also possible that the side face of the semiconductor component is formed in certain regions by side faces of the first and second semiconductor layers. In particular, all of the side faces of the semiconductor component are formed in certain regions by side faces of the first and/or second insulating layers.

According to at least one embodiment, the insulation extends to a first main face of the semiconductor component. In a non-limiting embodiment, the first main face is predominantly formed by a surface outwardly delimiting the semiconductor body, in particular the first main face of the semiconductor body. In this case, the first main face of the semiconductor component may be formed in certain regions by a surface of the insulation.

In a non-limiting embodiment, the first insulating layer extends to the first main face of the semiconductor component, so that the first main face of the semiconductor component is formed in certain regions by a surface of the first insulating layer. In addition or as an alternative, the second insulating layer may extend to the first main face, so that the first main face of the semiconductor component is formed in certain regions by surfaces of the first and/or second insulating layer.

In the case of a non-limiting refinement, the first and second insulating layers are formed from materials containing Si. The materials containing Si may be a stoichiometric or non-stoichiometric composition of silicon oxide or silicon nitride. Furthermore, materials containing Al, in particular a stoichiometric or non-stoichiometric composition of aluminum oxide, also come into consideration. In a non-limiting embodiment, the first and second insulating layers are formed from different materials. It is in this case advantageous if the two insulating layers differ in their etching behavior, in particular when using a wet-chemical etching process. For example, a comparatively good selectivity can be achieved in the case of a combination of layers in which one layer includes an SiO2 or NH3-containing SiNx and the other layer includes an NH3-free SiNx. One layer that contains Al2O3 and one layer that contains SiNx or SiO2 also represent a suitable combination. While NH3-free SiNx can scarcely be etched in wet etching processes, such as for example buffered oxide etching or KOH etching, NH3-containing SiNx and also SiO2 can be etched well in such processes. Furthermore, Al2O3 can scarcely be etched for example in fluorine-containing plasmas, but can be etched relatively well in chlorine-containing plasmas. For SiNx and SiO2, by contrast, the opposite applies.

According to at least one embodiment, the semiconductor body has at least one first recess, which extends from the second main face in the direction of the first main face of the semiconductor body and ends in the first semiconductor layer. The first recess is for example surrounded by the semiconductor body around the full periphery. The semiconductor body may have a plurality of such first recesses. In a non-limiting embodiment, the carrier layer is arranged in the at least one first recess. This advantageously serves for the electrical contacting of the first semiconductor layer, to be specific from the side of the second main face.

In the case of a non-limiting refinement, a surface of the semiconductor body that peripherally delimits the first recess is covered by the insulation. The insulation in this case extends from the second main face of the semiconductor body into the first recess.

Furthermore, the carrier layer may have at least one second recess, in which a terminal contact that serves for the electrical contacting of the second semiconductor layer is arranged. In particular, the second recess extends from a delimiting area of the carrier layer that is facing away from the semiconductor body through the carrier layer to a delimiting area of the carrier layer that is facing the semiconductor body. That is to say that the carrier layer is completely penetrated by the second recess. Furthermore, the second recess may continue into the region of the insulation arranged on the second main face and completely penetrate the insulation. In a non-limiting embodiment, a surface of the carrier layer that peripherally delimits the second recess is covered by a further insulating layer, which adjoins the insulation.

According to at least one embodiment, the semiconductor component has on the side of the second main face a first terminal contact for the electrical contacting of the first semiconductor layer and a second terminal contact for the electrical contacting of the second semiconductor layer. In this case, the first terminal contact may be connected in an electrically conducting manner to the carrier layer. Furthermore, the second terminal contact may be connected in an electrically conducting manner to a terminal layer, which is connected in an electrically conducting manner to the second semiconductor layer.

According to at least one embodiment, the semiconductor component has a molded-on main body, which is arranged on the semiconductor body. In the vertical direction, the carrier layer is arranged between the semiconductor body and the main body. In a non-limiting embodiment, the first and second terminal contacts are embedded in the main body. In this case, the first and second terminal contacts extend in particular from the side of the semiconductor body through the main body to a surface of the main body that is facing away from the semiconductor body.

The main body may for example be formed by a molding process. In particular, the main body is produced from a moldable plastic, for instance a polymer such as resin, epoxy or silicone. Advantageously, the plastics material of the main body may be protected by the carrier layer that is arranged between the semiconductor body and the main body from the electromagnetic radiation of the semiconductor body, which for example leads to accelerated aging of the main body. A molding process is generally understood as meaning a process by which a molding compound is shaped according to a prescribed form, with preference under the effect of pressure, and if required is cured. In particular, the term “molding process” includes molding, film assisted molding, injection molding, transfer molding and compression molding.

According to at least one embodiment of a method for producing a semiconductor component, it has the following steps:
providing a semiconductor body having
   a first semiconductor layer and a second semiconductor layer,
   a first main face and a second main face, opposite from the first main face, the first main face being formed by a surface of the first semiconductor layer and the second main face being formed by a surface of the second semiconductor layer,
   at least one side face, which joins the first main face to the second main face,
applying an electrically weakly conducting insulation to the second main face, the electrically weakly conducting insulation covering the second main face at least in certain regions and extending to at least one side face of the semiconductor body, and
having a first insulating layer and a second insulating layer, the second insulating layer being arranged on a side of the first insulating layer that is facing away from the semiconductor body and the first and second insulating layers differing from one another in their stiffness and/or elasticity,
applying an electrically conducting carrier layer to the electrically weakly conducting insulation.

In a non-limiting embodiment, the aforementioned method steps are carried out in the specified sequence.

According to at least one embodiment, the material that is used for the insulation or for the first and second insulating layers, for example TEOS (tetraethyl orthosilicate), may initially be applied in a gaseous state also to regions that are free of the insulation in the finished semiconductor component. The material is subsequently structured appropriately by a stripping away process, in particular by means of a wet chemical etching process or dry etching process, such as reactive ion etching (known as RIE). For example, the material of the insulation or of the first and second insulating layers may also be applied to the semiconductor body by means of atomic layer deposition (known as ALD). In particular, an aluminum oxide is suitable here as the material for the insulation or the first and second insulating layers.

According to at least one embodiment of the method, a starting layer is applied to the insulation, in particular is sputtered on or vapor-deposited. Furthermore, the carrier layer may be applied to the starting layer by means of a coating process, with preference by means of a galvanic coating process.

In the case of a non-limiting refinement, in addition the terminal contacts are applied to the semiconductor body by means of a coating process, with preference by means of a galvanic coating process. In this case, a further starting layer, which is in particular sputtered on or vapor-deposited, may serve as the seed layer for the terminal contacts. For example, the further starting layer may contain one of the materials Au, Ti, Cu, Al, Ag, Sn, Rh, Ni or Pt or consist of one of these materials.

The first and second semiconductor layers may be produced layer by layer one after the other on a growth substrate by means of an epitaxial process. Sapphire, SiC and/or GaN for example come into consideration as materials for the growth substrate. The growth substrate may be at least partially removed after the production of the semiconductor body, so that the first main face or a surface of the first semiconductor layer is at least partially exposed. In particular, the semiconductor body may be exposed to the extent that the insulation appears. This has the effect in particular that the first main face of the semiconductor component is formed in certain regions by a surface of the insulation. The working of the semiconductor body may be performed by means of an etchant.

For example, only the first insulating layer or else the first and second insulating layers may be exposed in certain regions. Furthermore, it is possible that between the carrier layer and the first insulating layer or between the semiconductor body and the second insulating layer there is formed a cavity, which extends from the first main face, along at least one side face of the semiconductor body, in the direction of the second main face. For this, the etchant that is used may penetrate into a region between the semiconductor body and the carrier layer and form a cavity.

For producing a plurality of semiconductor components, a wafer assemblage may be provided, having a series of semiconductor layers including a first semiconductor layer and a second semiconductor layer, a plurality of first terminal contacts, a plurality of second terminal contacts and at least one or a plurality of continuous insulation(s) as well as at least one or a plurality of continuous carrier layer(s). The wafer assemblage may have a plurality of separating trenches, along which the wafer assemblage can be divided up into a plurality of semiconductor components. A complete penetration of the series of semiconductor layers by the separating trenches is not necessary here. Rather, the separating trenches may extend through the second semiconductor layer and the active layer into the first semiconductor layer and end there. Alternatively, it is also possible that the separating trenches extend in the vertical direction through the entire wafer assemblage, so that separate semiconductor bodies or semiconductor components are already produced by the formation of the separating trenches. This variant is advantageous in particular when the semiconductor bodies are to be covered at the side faces with a material, for example with a reflective material.

According to at least one embodiment of a method for producing one or a plurality of the semiconductor components described here, a main body assemblage is molded onto the wafer assemblage. For forming the main body assemblage, a material suitable for it is applied to the wafer assemblage in such a way that the separating trenches and intermediate regions between the terminal contacts are at least partially or completely filled. In a subsequent method step, the wafer assemblage and the main body assemblage are singulated along the separating trenches into a plurality of semiconductor components in such a way that the semiconductor components have in each case a semiconductor body, an insulation, a carrier layer and a main body, a first terminal contact and a second terminal contact being embedded in the main body.

For example, the wafer assemblage and the main body assemblage may be sawn up or divided up by a laser separating process. The mechanical loads thereby produced can be advantageously reduced by the first or second insulating layer. In this way it is possible to suppress the occurrence of defects.

The method described above is particularly suitable for the production of one or a plurality of the semiconductor components described here. Therefore, features described in connection with the semiconductor component can also be used for the method, and vice versa.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the illumination apparatus. In the following description, various aspects are described with reference to the following drawings, in which:

FIG. 1A shows a schematic plan view and FIG. 1B shows a schematic cross-sectional view of a method step and of a semiconductor component in an intermediate stage of a method according to an embodiment,

FIG. 2A shows a schematic plan view and FIG. 2B shows a further schematic cross-sectional view of the same method step and of the same semiconductor component in the intermediate stage of the method according to the previous embodiment,

FIG. 3 shows a schematic cross-sectional view of a method step and of a semiconductor component in a final stage of a method according to a first embodiment,

FIG. 4 shows a schematic cross-sectional view of a method step and of a semiconductor component in a final stage of a method according to a second embodiment,

FIG. 5 shows a schematic cross-sectional view of a method step and of a semiconductor component in a final stage of a method according to a third embodiment,

FIG. 6 shows a schematic cross-sectional view of a method step and of a semiconductor component in a final stage of a method according to a fourth embodiment,

FIG. 7 shows a schematic cross-sectional view of a method step and of a wafer assemblage and a main body assemblage in an intermediate stage of a method according to an embodiment,

FIG. 8 shows a comparative example of a semiconductor component in a schematic cross-sectional view,

FIG. 9 shows an FIB (known as a focused ion beam) micrograph of a semiconductor component according to a comparative example.

### DETAILED DESCRIPTION

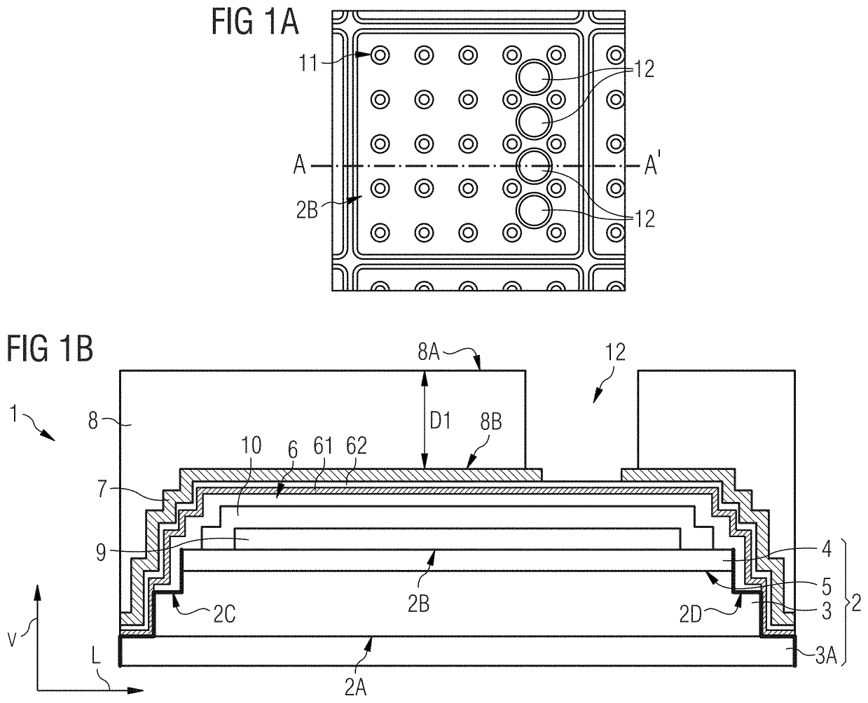

FIGS. 1A and 1B illustrate an intermediate stage of a method for producing a semiconductor component 1 and an intermediate stage of a semiconductor component 1 described in the present case. FIG. 1A shows the unfinished semiconductor component 1 in a plan view of a second main face 2B of the semiconductor body 2. FIG. 1B shows a cross section of the unfinished semiconductor component 1 along the line AA′ represented in FIG. 1A.

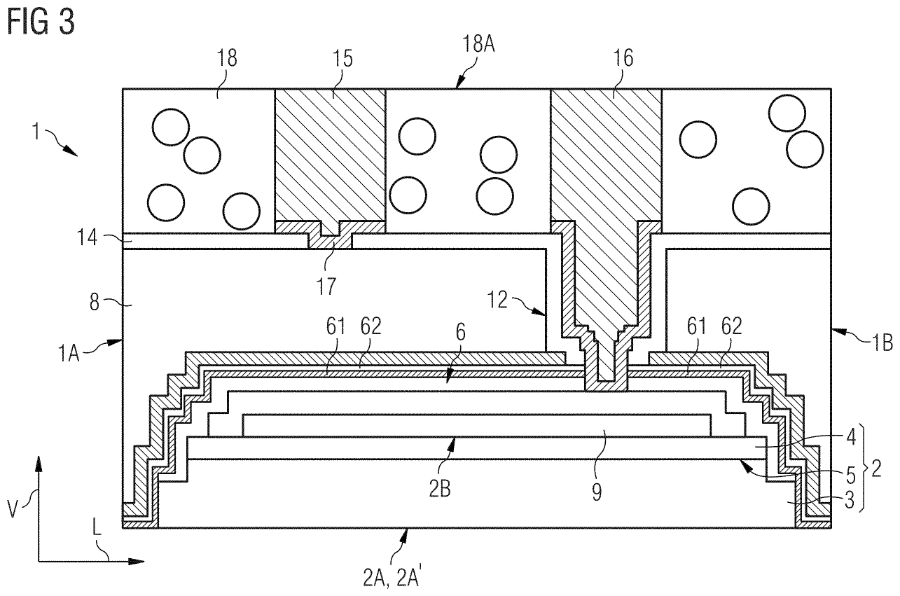

The unfinished semiconductor component 1 includes a semiconductor body 2 with a first semiconductor layer 3, a second semiconductor layer 4 and a growth substrate 3A, on which the first and second semiconductor layers 3, 4 are arranged. Furthermore, the semiconductor body 2 has a first main face 2A and a second main face 2B, opposite from the first main face 2A, the first main face 2A being formed by a surface of the first semiconductor layer 3 and the second main face 2B being formed by a surface of the second semiconductor layer 4. In addition, the semiconductor body 2 has multiple side faces 2C, 2D, which join the first main face 2A to the second main face 2B. In particular, the first main face 2A and the second main face 2B delimit the semiconductor body 2 in the finished semiconductor component (cf. FIG. 3) in a vertical direction V, while the side faces 2C, 2D delimit the semiconductor body 2 in lateral directions L. The lateral directions L in this case run transversely, in particular perpendicularly, to the vertical direction V. The side faces 2C, 2D may be made up in each case of multiple sub-faces, in particular the individual sub-faces being in each case planar surfaces and the surface normals of two sub-faces that are adjacent to one another running transversely, that is to say not parallel, to one another.

Between the first semiconductor layer 3 and the second semiconductor layer 4, the semiconductor body 2 has an active zone 5, which is intended for radiation generation. In particular, the active zone 5 is a p-n junction zone. The active zone 5 may in this case be formed as one layer or as a series of multiple layers.

The first semiconductor layer 3 may have a first conductivity and the second semiconductor layer 4 may have a second conductivity. In a non-limiting embodiment, the first semiconductor layer 3 is an n-conducting layer. Furthermore, the second semiconductor layer 4 is in particular a p-conducting layer.

Materials based on nitride-compound semiconductors come into consideration for the layers of the semiconductor body 2.

The semiconductor component 1 includes an electrically conducting carrier layer 8, which covers the second main face 2B and the side faces 2C, 2D of the semiconductor body 2 at least in certain regions. In this case, the carrier layer 8 extends from the second main face 2B over side faces of the second semiconductor layer 4 to side faces of the first semiconductor layer 3. For example, Au, Zn, Al, Sn, Ni and Cu or compounds of these materials, such as for example AuSn and NiAu and additionally NiPdAu, come into consideration for the carrier layer 8. The carrier layer 8 may contain at least one of these materials or consist of one of these materials. The carrier layer 8 is in particular a galvanic layer, which is galvanically deposited on a starting layer 7 arranged on the semiconductor body 2. For example, the starting layer 7 may contain one of the materials Au, Ti, Cu, Al, Ag, Sn, Rh, Ni or Pt or consist of one of these materials. Because of its nature, for example its thickness and/or its material, the carrier layer 8 is a stabilizing component of the semiconductor component 1. The thickness D1 of the carrier layer 8 may be between 2 μm and 100 μm inclusive, in particular between 5 μm and 30 μm, between 5 μm and 15 μm, deviations from the values specified of up to 10% being tolerable.

Furthermore, the semiconductor component 1 has an electrically weakly conducting insulation 6, which is arranged between the carrier layer 8 and the semiconductor body 2. In this case, the second main face 2B is covered at least in certain regions by the insulation 6. Furthermore, the insulation 6 extends from the second main face 2B along the side faces of the second semiconductor layer 4 to the side faces of the first semiconductor layer 3.

The insulation 6 is of a multilayer form, including a first insulating layer 61 and a second insulating layer 62. The second insulating layer 62 is arranged on a side of the first insulating layer 61 that is facing away from the semiconductor body 2. The first and second insulating layers 61 extend from the second main face 2B over side faces of the second semiconductor layer 4 to side faces of the first semiconductor layer 3. For example, the first and second insulating layers 61, 62 are formed from materials containing Si. In a non-limiting embodiment, the first and second insulating layers are formed from different materials. The materials containing Si may be a stoichiometric or non-stoichiometric composition of silicon oxide or silicon nitride. Furthermore, materials containing Al, in particular a stoichiometric or non-stoichiometric composition of aluminum oxide, also come into consideration.

Between the insulation 6 and the semiconductor body 2, the semiconductor component 1 may have further layers. For example, a terminal layer 9, which directly adjoins the second semiconductor layer 4, may be provided. With preference, the terminal layer 9 is formed from an electrically conducting and highly reflective material. For example, the terminal layer 9 is an electrically conducting mirror layer. For example, the terminal layer 9 may contain Ag or consist thereof. However, it is also possible that the terminal layer 9 is formed from a transparent conducting oxide (transparent conductive oxides, “TCO” for short), such as for example zinc oxide.

Furthermore, a current spreading layer 10 may be arranged adjacent to the terminal layer 9. The current spreading layer 10 may be formed as a stack of layers including multiple metal layers. In particular, the current spreading layer 10 may include metals such as Pt, Au, Cu, Al, Ag, Sn, Rh and Ti.

In the case of the embodiment represented, the carrier layer 8 has a number of second recesses 12, in which a second terminal contact can in each case be arranged. In particular, the second recesses 12 extend in each case from a delimiting area 8A of the carrier layer 8 that is facing away from the semiconductor body 2 through the carrier layer 8 to a delimiting area 8B of the carrier layer 8 that is facing the semiconductor body 2. That is to say that the carrier layer 8 is completely penetrated in the vertical direction V by the second recess 12. Furthermore, the second recess 12 may continue into the insulation 6 and completely penetrate it (cf. FIG. 3).

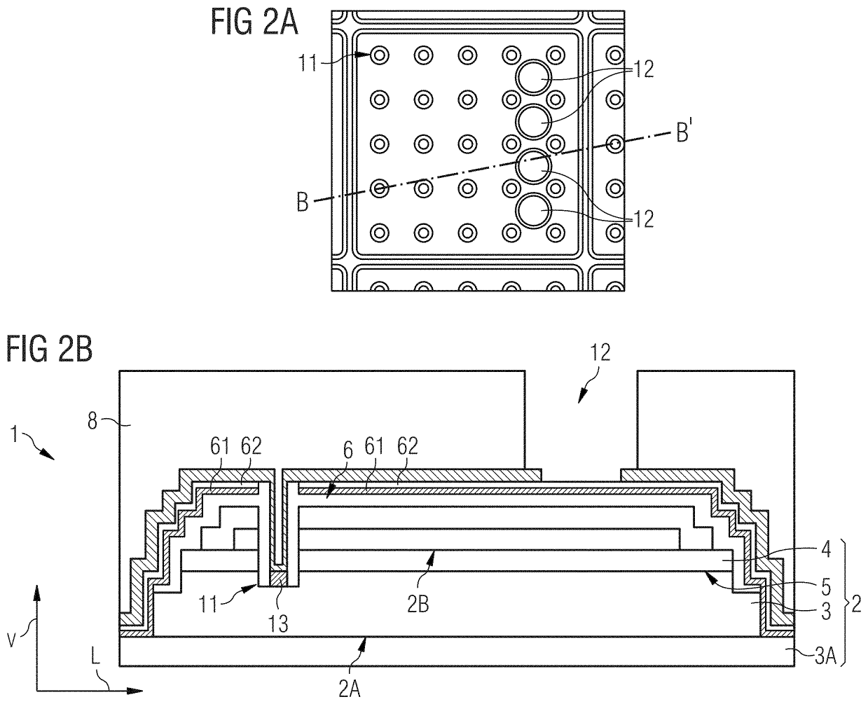

FIG. 2B shows the intermediate stage described above of a method and of a semiconductor component 1 in another view, a cross section along the line BB′ that is represented in FIG. 2A being shown in FIG. 2B.

The semiconductor body 2 has a first recess 11, which extends from the second main face 2B in the direction of the first main face 2A and ends in the first semiconductor layer 3. The first recess 11 is surrounded in lateral directions L around the full periphery by the semiconductor body 2. As can be seen from FIG. 2A, the semiconductor body 2 has a plurality of such first recesses 11. In the first recess 11, the carrier layer 8 is arranged. This advantageously serves for the electrical contacting of the first semiconductor layer 3 from the side of the second main face 2B. For improved electrical contacting of the first semiconductor layer 3, a contact element 13 may be arranged in direct contact with it in the first recess 11.

A surface of the semiconductor body 2 that peripherally delimits the first recess 11 is covered by the insulation 6. The insulation 6 in this case extends from the second main face 2B of the semiconductor body 2 into the first recess 11. The carrier layer 8 arranged in the recess 11 is electrically insulated from the adjacent layers by the insulation 6 laterally surrounding it.

Between the intermediate stage, described in connection with FIGS. 1 and 2, and the final stage, represented in FIG. 3, of a method and of a semiconductor component 1, further method steps are performed.

On the one hand, a further insulating layer 14 is formed on a delimiting area 8A of the carrier layer 8 that is facing away from the semiconductor body 2, the insulating layer 14 extending into the recess 12. On the other hand, terminal contacts 15, 16 are formed. In this case, a further starting layer 17, which is in particular sputtered on or vapor-deposited, may serve as the seed layer for the terminal contacts 15, 16. In addition, a main body 18, into which the terminal contacts 15, 16 are embedded, is molded on. The main body 18 advantageously represents a further stabilizing component. The growth substrate 3A may be at least partially removed, so that the first main face 2A or a surface of the first semiconductor layer 3 is at least partially exposed. For the stripping away of the growth substrate 3A, a laser lifting process or an etching process comes into consideration for example.

FIG. 3 shows a finished semiconductor component 1 in a cross-sectional view along the line AA′ represented in FIG. 1A. The semiconductor component 1 is in particular an optoelectronic semiconductor component. The semiconductor component 1 is intended for the emission of radiation. In this case, during the operation of the semiconductor component 1 the active zone 5 can emit electromagnetic radiation, for instance in the visible, ultraviolet or infrared spectral range. In particular, the electromagnetic radiation is predominantly coupled out of the semiconductor component 1 at the first main face 2A′.

The semiconductor component 1 has a first terminal contact 15 for the electrical contacting of the first semiconductor layer 3 and a second terminal contact 16 for the electrical contacting of the second semiconductor layer 4. In this case, the first terminal contact 15 is in electrical contact with the carrier layer 8. Furthermore, the second terminal contact 16 is arranged in the second recess 12 and extends in the vertical direction V through the carrier layer 8 and the insulation 6, the second terminal contact 16 being in electrical contact with the terminal layer 9. The second terminal contact 16 is electrically insulated from the carrier layer 8 by the further insulating layer 14 arranged in the recess 12. The further insulating layer 14 may be formed from an electrically insulating material, such as silicon oxide and/or silicon nitride.

Furthermore, the semiconductor component 1 has a molded-on main body 18, which is arranged on the semiconductor body 2. In the vertical direction V, the insulation 6 and the carrier layer 8 are arranged between the semiconductor body 2 and the main body 18. The first and second terminal contacts 15, 16 extend from the side of the semiconductor body 2 through the main body 18 to a surface 18A of the main body 18 which is arranged on a side of the main body 18 that is facing away from the semiconductor body 2. The terminal contacts 15, 16 are enclosed in lateral directions L around the full periphery by the main body 18.

In the case of the embodiment represented, side faces 1A, 1B of the semiconductor component 1 are formed in certain regions by side faces of the carrier layer 8 and of the insulation 6. In this case, both side faces of the first insulating layer 61 and side faces of the second insulating layer 62 form part of the side faces 1A, 1B of the semiconductor component 1. The semiconductor component 1 is therefore partially delimited in lateral directions L by side faces of both insulating layers 61, 62. Furthermore, the first insulating layer 61 extends to the first main face 2A′ of the semiconductor component 1, so that the first main face 2A′ of the semiconductor component 1 is formed in certain regions by a surface of the first insulating layer 61.

The two insulating layers 61 and 62 may be formed from different materials and have different elasticities. The second insulating layer 62 advantageously has a greater elasticity than the first insulating layer 61. As a result, the second insulating layer 62 is more easily deformable than the first insulating layer 61, so that stresses that occur for example during the assembly or production of the semiconductor component 1 can be reduced better by means of the second insulating layer 62 than by the first insulating layer 61. However, it is also possible that the second insulating layer 62 is more rigid, that is to say in particular is formed with a lower elasticity, than the first insulating layer 61, so that the second insulating layer 62 serves as a predetermined breaking point. Overall, mechanical loads in the semiconductor component 1 can therefore be specifically reduced by the second insulating layer 62. In this case, it proves to be advantageous that the second insulating layer 62 is arranged close to the less flexible carrier layer 8, and consequently can compensate for stresses occurring in the region of the carrier layer 8.

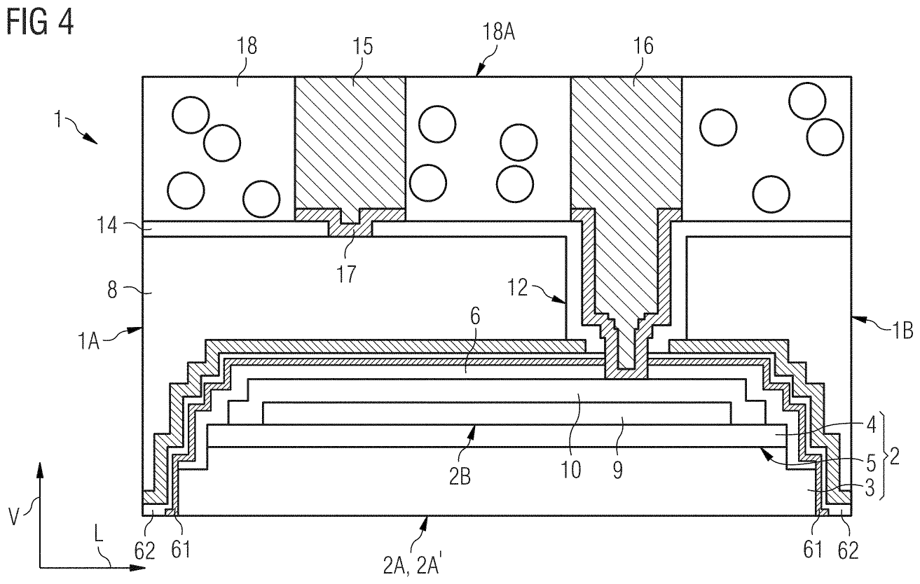

FIG. 4 illustrates a final stage of a method for producing a semiconductor component 1 and a semiconductor component 1 according to a second embodiment.

The semiconductor component 1 includes a semiconductor body 2 as well as a carrier layer 8, arranged on the semiconductor body 2, and a main body 18, arranged on said carrier layer. Between the carrier layer 8 and the semiconductor body 2, the semiconductor component 1 has a terminal layer 9, a current spreading layer 10 and an insulation 6. The semiconductor body 2 and the further elements already mentioned in connection with the first embodiment have the aforementioned properties.

With regard to their structure, however, the insulation 6 according to the second embodiment differs from the first embodiment. In the case of the second embodiment, the side faces 1A, 1B of the semiconductor component 1 are formed in certain regions by side faces of the second insulating layer 62, but not by side faces of the first insulating layer 61. Furthermore, the second insulating layer 62 also extends to the first main face 2A′, so that the first main face 2A′ of the semiconductor component 1 is formed in certain regions by surfaces of the first and second insulating layer 61, 62. In the case of the second embodiment, as a result of the region on the first main face 2A′, the second insulating layer 62 has a larger exposed surface than in the case of the first embodiment, which further assists the deformability of the second insulating layer 62.

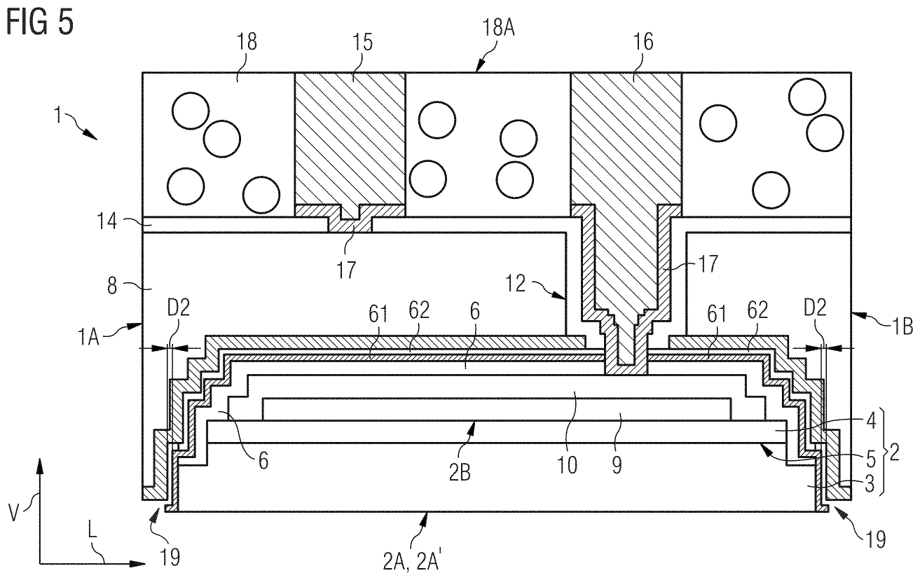

FIG. 5 illustrates a final stage of a method for producing a semiconductor component 1 or a semiconductor component 1 according to a third embodiment.

The semiconductor component 1 includes a semiconductor body 2 as well as a carrier layer 8, arranged on the semiconductor body 2, and a main body 18, arranged on said carrier layer.

Between the carrier layer 8 and the semiconductor body 2, the semiconductor component 1 has a terminal layer 9, a current spreading layer 10 and an insulation 6. The semiconductor body 2 and the further elements already mentioned in connection with the first embodiment have the aforementioned properties.

With regard to their structure, however, the insulation 6 according to the third embodiment differs from the first embodiment. In the case of the third embodiment, the side faces 1A, 1B of the semiconductor component 1 are formed in certain regions by side faces of the first insulating layer 61, but not by side faces of the second insulating layer 62. Furthermore, only the first insulating layer 61 extends to the first main face 2A′ of the semiconductor component 1, so that the first main face 2A′ of the semiconductor component 1 is formed in certain regions by a surface of the first insulating layer 61. Between the insulation 6 and the carrier layer 8 there is formed at least one cavity 19, in which the second insulating layer 62 is stripped away. That is to say that the cavity 19 is free of the second insulating layer 62. The cavity 19 may extend from the first main face 2A′ of the semiconductor component 1, along at least one side face 2C, 2D of the semiconductor body 2, in the direction of the second main face 2B of the semiconductor body 2. The cavity 19 may surround the semiconductor body 2 laterally around the full periphery. Alternatively, a number of cavities 19 may be provided in the second insulating layer 62, a region of the second insulating layer 62 being respectively arranged between two cavities 19. For example, the cavity 19 may have a thickness D2 of 50 nm to 2 μm, between 100 nm and 500 nm. The thickness D2 of the cavity 19 may correspond to the layer thickness of the second insulating layer 62 or deviate from it by 10% to 50%. The size of the cavity 19 is set such that there is compensation for stresses.

The at least one cavity 19 allows the various layers in the semiconductor component 1 to have space for slight flexural distortions, without directly causing defects in the semiconductor component 1. In particular, the structuring of the second insulating layer 62, that is to say an altered geometrical shape of the second insulating layer 62, can have the effect that the stiffness of the second insulating layer 62 is reduced as compared to the first insulating layer 61, even when there is equally great elasticity.

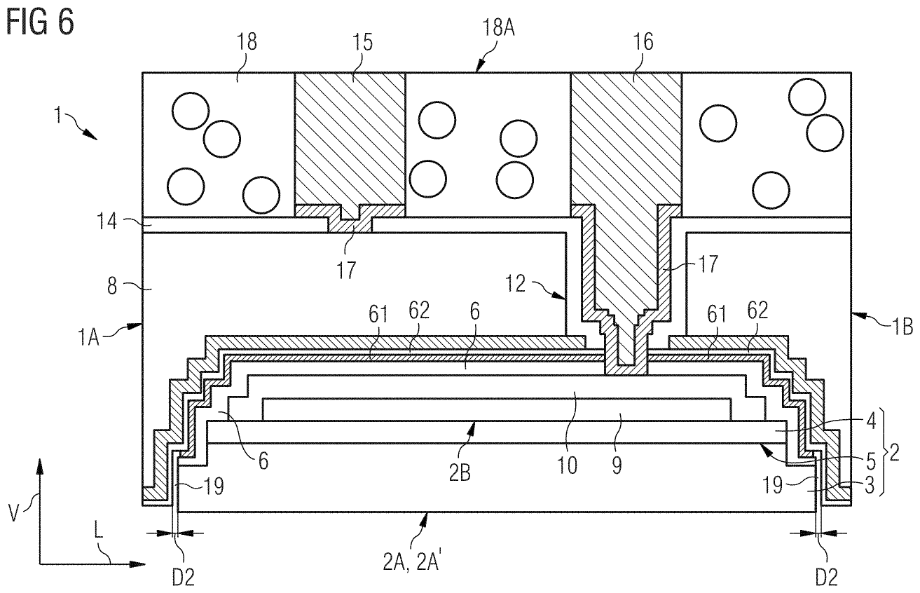

FIG. 6 illustrates a final stage of a method for producing a semiconductor component 1 or a semiconductor component 1 according to a fourth embodiment.

With regard to its structure, the insulation 6 according to the fourth embodiment differs from the third embodiment. In the case of the fourth embodiment, the side faces 1A, 1B of the semiconductor component 1 are formed in certain regions by side faces of the second insulating layer 62, but not by side faces of the first insulating layer 61. Furthermore, only the second insulating layer 62 extends to the first main face 2A′ of the semiconductor component 1, so that the first main face 2A′ of the semiconductor component 1 is formed in certain regions by a surface of the second insulating layer 62. Between the semiconductor body 2 and the carrier layer 8 there is formed at least one cavity 19, in which the first insulating layer 61 is stripped away. That is to say that the cavity 19 is free of the first insulating layer 61. The cavity 19 may extend from the first main face 2A′ of the semiconductor component 1, along at least one side face 2C, 2D of the semiconductor body 2, in the direction of the second main face 2B of the semiconductor body 2. The cavity 19 may surround the semiconductor body 2 laterally around the full periphery. Alternatively, a number of cavities 19 may be provided in the first insulating layer 61, a region of the first insulating layer 61 being respectively arranged between two cavities 19. For example, the cavity 19 may have a thickness D2 of 50 nm to 2 μm, between 100 nm and 500 nm. The thickness D2 of the cavity 19 may correspond to the layer thickness of the first insulating layer 61 or deviate from it by 10% to 50%. The size of the cavity 19 is set such that there is compensation for stresses.

The at least one cavity 19 allows the various layers in the semiconductor component 1 to have space for slight flexural distortions, without directly causing defects in the semiconductor component 1. In particular, the structuring of the first insulating layer 61, that is to say an altered geometrical shape of the first insulating layer 61, can have the effect that the stiffness of the first insulating layer 61 is reduced as compared to the second insulating layer 62, even when there is equally great elasticity.

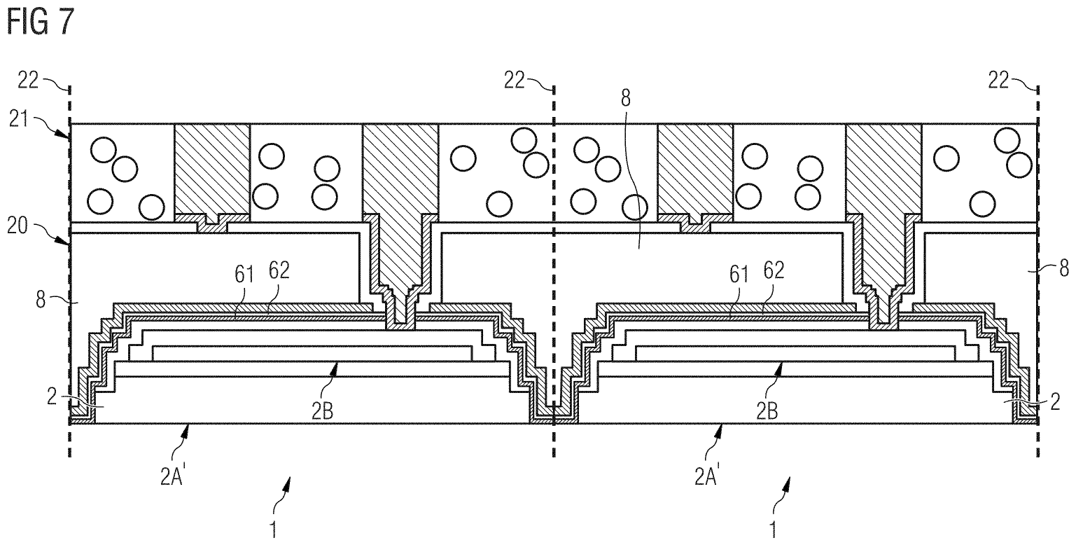

FIG. 7 illustrates the production of a plurality of semiconductor components 1. This involves providing a wafer assemblage 20 having a molded-on main body assemblage 21, the wafer assemblage 20 having a plurality of semiconductor bodies 2 and a carrier layer 8, joining the semiconductor bodies 2, as well as a first insulating layer 61 and a second insulating layer 62, arranged between the semiconductor bodies 2 and the carrier layer 8. In addition, a number of separating trenches 22 are provided, along which the wafer assemblage 20 and the main body assemblage 21 can be separated into a plurality of semiconductor components 1. The first and second insulating layers 61, 62 extend into the separating trenches 22 and in the region of the separating trenches 22 are formed without any interruption.

For producing semiconductor components 1 according to the first embodiment, the first and second insulating layers 61, 62 are left without any interruption in the region of the separating trenches 22.

For producing semiconductor components 1 according to the second embodiment, the wafer assemblage 20 is worked further, the first insulating layer 61 on the first main face 2A′ being at least partially removed, so that the second insulating layer 62 appears (not represented in FIG. 7).

For producing semiconductor components 1 according to the third and fourth embodiments, the wafer assemblage 20 is likewise worked further in comparison with the stage represented in FIG. 7, stripping away of the second insulating layer 62 and of the first insulating layer 61 having the effect of creating cavities, which extend in each case from the first main face 2A′, along at least one side face of a semiconductor body 2, in the direction of the second main face 2B.

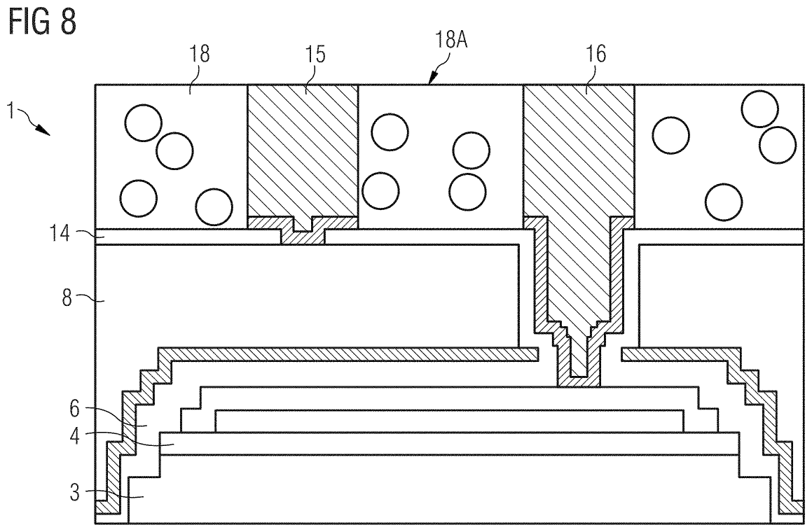

FIG. 8 shows a comparative example of a semiconductor component 1, which as a difference from the semiconductor components 1 described in connection with FIGS. 3, 4, 5 and 6 does not have an insulation with insulating layers of different characteristics. As a consequence, because of the rigidity of the carrier layer 7, defects, for example cracks and delaminations, may occur in the course of production or assembly and impair the mechanical stability of the semiconductor component 1.

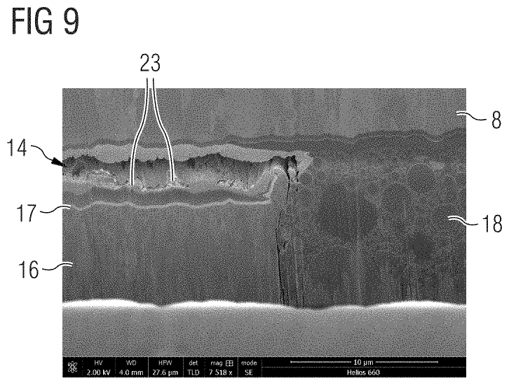

FIG. 9 shows in an FIB micrograph a detail of the cross section of a comparative example, as represented in FIG. 8, of a semiconductor component that has a largely homogeneous insulation. The semiconductor component 1 exhibits defects 23 in the further insulating layer 14, which can be prevented by means of an insulation as described in the present case.

The invention is not restricted by the description on the basis of the embodiments. Rather, the invention includes every novel feature and every combination of features, which includes in particular any combination of features in the patent claims, even if this feature or this combination itself is not explicitly specified in the patent claims or embodiments.

### LIST OF REFERENCE SIGNS

1 Semiconductor component
1A, 1B Side face
2 Semiconductor body
2A, 2A′ First main face
2B Second main face
2C, 2D Side face
3 First semiconductor layer
3A Growth substrate
4 Second semiconductor layer
5 Active zone
6 Insulation
61 First insulating layer
62 Second insulating layer
7, 17 Starting layer
8 Carrier layer
8A, 8B Delimiting area
9 Terminal layer
10 Current spreading layer
11 First recess
12 Second recess
13 Contact element
14 Insulating layer
15 First terminal contact
16 Second terminal contact
18 Main body
18A Surface
19 Cavity
20 Wafer assemblage
21 Main body assemblage
22 Separating trench
23 Defect
D1, D2 Thickness
V Vertical direction
L Lateral directions

1. A semiconductor component comprising:
a semiconductor body having:
a first semiconductor layer and a second semiconductor layer;
a first main face and a second main face (2B), opposite from the first main face, the first main face being formed by a surface of the first semiconductor layer and the second main face being formed by a surface of the second semiconductor layer;
at least one side face joining the first main face to the second main face;
an electrically conducting carrier layer covering the second main face at least in certain regions; and
an electrically weakly conducting insulation; which
is arranged between the carrier layer and the semiconductor body;
covers the second main face at least in certain regions and extends to at least one side face of the semiconductor body; and
has a first insulating layer and a second insulating layer, the second insulating layer being arranged on a side of the first insulating layer that is facing away from the semiconductor body and the first and second insulating layers differing from one another in their stiffness and/or elasticity, wherein the second insulating layer has a structuring in such a way that at least one cavity is formed between the electrically weakly conducting insulation and the electrically conducting carrier layer and/or the first insulating layer has a structuring in such a way that at least one cavity is formed between the semiconductor body and the electrically conducting carrier layer.

2. (canceled)

3. (canceled)

4. The semiconductor component as claimed in claim 1, wherein the cavity extends from a first main face of the semiconductor component, along at least one side face of the semiconductor body, in the direction of the second main face of the semiconductor body.

5. The semiconductor component as claimed in claim 1,
wherein the electrically weakly conducting insulation extends from the second main face to at least one side face of the first semiconductor layer, and at least one side face of the second semiconductor layer being completely covered by the electrically weakly conducting insulation.

6. The semiconductor component as claimed in claim 1,
wherein the electrically weakly conducting insulation being conformally covered by the electrically conducting carrier layer.

7. The semiconductor component as claimed in claim 1, wherein at least one side face of the semiconductor component being formed in certain regions by a side face of the first and/or second insulating layer.

8. The semiconductor component as claimed in claim 1, wherein the electrically weakly conducting insulation extending to a first main face of the semiconductor component.

9. The semiconductor component as claimed in claim 1, wherein the first insulating layer and the second insulating layer are formed from different materials.

10. The semiconductor component as claimed in claim 1, wherein the first insulating layer and the second insulating layer are formed from materials comprising Si.

11. The semiconductor component as claimed in claim 1, wherein
the semiconductor body has at least one first recess, which extends from the second main face in the direction of the first main face and ends in the first semiconductor layer, the electrically conducting carrier layer being arranged in the first recess and serving for the electrical contacting of the first semiconductor layer.

12. The semiconductor component as claimed claim 1, wherein a surface of the semiconductor body that peripherally delimits the first recess is covered by the electrically weakly conducting insulation.

13. The semiconductor component as claimed in claim 1, wherein
the carrier layer has at least one second recess, in which a terminal contact that serves for the electrical contacting of the second semiconductor layer is arranged.

14. The semiconductor component as claimed in claim 13, wherein a surface of the carrier layer that peripherally delimits the second recess is covered by a further insulating layer, which adjoins the electrically weakly conducting insulation.

15. The semiconductor component as claimed in claim 1, further comprising
a molded-on main body, which is arranged on the semiconductor body, the electrically conducting carrier layer being arranged in the vertical direction between the semiconductor body and the main body.

16. A method for producing a semiconductor component as claimed in claim 1, wherein the method comprises:
providing a semiconductor body having
a first semiconductor layer and a second semiconductor layer;
a first main face and a second main face, opposite from the first main face, the first main face being formed by a surface of the first semiconductor layer and the second main face being formed by a surface of the second semiconductor layer;
at least one side face joining the first main face to the second main face;
applying an electrically weakly conducting insulation to the second main face, the electrically weakly conducting insulation covering the second main face at least in certain regions and extending to at least one side face of the semiconductor body; and
having a first insulating layer and a second insulating layer, the second insulating layer being arranged on a side of the first insulating layer that is facing away from the semiconductor body and the first and second insulating layers differing from one another in their stiffness and/or elasticity, and wherein the second insulating layer has a structuring in such a way that at least one cavity is formed between the electrically weakly conducting insulation and the electrically conducting carrier layer and/or the first insulating layer has a structuring in such a way that at least one cavity is formed between the semiconductor body and the electrically conducting carrier layer;
applying an electrically conducting carrier layer to the electrically weakly conducting insulation.

17. (canceled)
